(19) United States
(12) Patent Application Publication
(10) Pub. No.: US 2002/0148402 A1
(43) Pub. Date: Oct. 17, 2002

(54) Growing of homogeneous crystals by bottom solid feeding

(76) Inventors: Sindo Kou, Madison, WI (US); Jia-Jie He, Madison, WI (US)

Correspondence Address: Harry C. Engstrom, FOLEY & LARDNER, 150 East Gilman Street, P.O. Box 1497, Madison, WI, 53701-1497, US

(21) Appl. No.: 09/834,791

(22) Filed: Apr. 13, 2001

(51) Int. Cl. C30B 15/00; C30B 21/06; C30B 27/02; C30B 28/10; C30B 30/04

(52) U.S. Cl. 117/13

(57) ABSTRACT

Crystals of doped semiconductors and alloys are grown in a Czochralski process utilizing a single crucible. An upper heater around the crucible applies heat to an upper portion of the crucible while a lower heater below the upper heater applies heat to a lower portion of the crucible independently of the upper heater. A solid feed material in a lower portion of the crucible is maintained by the lower heater at a temperature below the melting point of the feed material, while the upper heater maintains an upper portion of the crucible at a higher temperature to provide a melt of the feed material in the upper portion of the crucible. A crystal grown from a seed introduced into the melt is drawn upwardly from the melt, and through a liquid encapsulant layer for a liquid encapsulated Czochralski process, and the crucible is displaced relative to the upper and lower heaters to bring additional portions of the solid feed material into the higher temperature region of the upper heater to replenish the melt drawn out with the formed crystal, avoiding spatial segregation of dopants or of constituents of an alloy.

### REFERENCE TO GOVERNMENT RIGHTS

This invention was made with United States government support awarded by the following agency: NSF 9709944. The United States government has certain rights in this invention.

### FIELD OF THE INVENTION

This invention pertains to the field of crystal growth by the Czochralski process and particularly to the growth of crystals by the liquid encapsulated Czochralski process.

### BACKGROUND OF THE INVENTION

Compositionally uniform semiconductor crystals are required for the manufacturing of a variety of devices, including integrated circuits, photodetectors, solar cells, thermoelectric devices, x-ray, gamma ray and neutron monochromators, power FETs, diode lasers, infrared detectors, pollution detectors for carbon dioxide and other pollutant gases, etc. Such crystals are often grown with a small amount of an impurity as a dopant, e.g., indium doped gallium arsenide, or as alloys of two or more semiconductors. The crystals must be compositionally homogeneous to be useful. Spatial segregation in the crystal of dopants or alloys would result in variations in the physical properties of the devices made with the crystals, and for the case of alloy crystals, could promote polycrystalline growth or even cracking. For example, GaAs single crystals have been doped with InAs to reduce dislocations, and such crystals are referred to as In-doped GaAs. The effect of segregation coefficient k for InAs in In-doped GaAs is small, from 0.1 to 0.13. Consequently, InAs tends to segregate along a GaAs crystal.

The liquid-encapsulated Czochralski (LEC) process has been the most widely used process to grow GaAs crystals. B₂O₃ is typically used as a liquid encapsulant under pressurized Ar to suppress As evaporation from the melt. In order to reduce dopant segregation, efforts have been made to use double-crucible techniques for growing doped GaAs crystals. In a double-crucible process, the crystal is grown from a growth melt held in an inner crucible, and the growth melt is fed with a replenishing melt held in the outer crucible. A high temperature shutter has been used to regulate the flow of the melt from the outer, replenishing crucible into the inner crucible. While such double crucible processes have been successfully utilized for growing uniform silicon crystals, the double crucible technique is less suited to use with crystals requiring liquid encapsulation, such as GaAs. A primary problem is that the liquid encapsulant, e.g., boric oxide for GaAs, tends to plug up the passageway(s) between the inner and outer crucibles. Further, the inner crucible has commonly been prepared from hot pressed BN because the crucible walls need to be very thick to maintain a temperature differential between the inner and outer crucibles. The hot pressed BN is not nearly as clean as the pyrolytic BN crucibles with relatively thin walls that are preferred for growing GaAs crystals. In addition, the two crucibles are commonly quite large and much of the expensive, high-purity charge for crystal growth is left over at the end of a run and consequently wasted. This leftover charge cannot be utilized because of its unknown characteristics, partly due to the contamination from the hot pressed BN crucible, but also because of the way crystals tend to develop a severe segregation during crystal growth, leaving a higher concentration of dopant in the remaining melt. Attempts to utilize double-crucible techniques to grow uniform crystals in In-doped GaAs have been reported but with relatively limited success. See, e.g., H. Okada, et al., J. Crystal Growth, Vol. 82, 1987, pp. 643 et seq.; J. He, et al, J. Crystal Growth, Vol. 208, 2000, pp. 42-48; J. He, et al., J. Crystal Growth, Vol. 211, 2000, pp. 163-168; R. M. Ware, Technical Report ADA 297039, Defense Technical Information Center, Ft. Belvoir, Va., 1995; K. Nakajima, et al., Materials Research Society Symposium Proceedings, Vol. 281, 1993, p. 197; K. Nakajima, et al., J. Crystal Growth, Vol. 169, 1996, pp. 217-222.

Lin, et al. (M. H. Lin, et al., J. Crystal Growth, Vol. 193, 1998, pp. 443-445) have reported a reduction in segregation in Czochralski growth of Cd-doped InSb by using an elongated crucible to accommodate a solid feed below the melt. The crystal was pulled from a molten zone on the solid feed. There was no liquid encapsulant covering the melt. A single heater was used and the crucible was raised to cause the solid feed to replenish the melt above it.

### SUMMARY OF THE INVENTION

In accordance with the invention, crystals of doped semiconductors or alloys are grown with homogeneous composition along the length of the crystal rod. Spatial segregation of dopants or of one of the constituents of an alloy is essentially avoided, allowing high quality devices to be manufactured from sections of the crystal rod along essentially the entire length of the rod. The invention is particularly well adapted for growing of crystals of materials requiring liquid encapsulation, such as GaAs.

Apparatus for crystal growth in accordance with the invention includes a crucible having a preferably flat bottom, a sidewall, and an open top, with an axial height from the open top to the bottom, an upper heater around the crucible to apply heat to an upper portion of the crucible, a lower heater around the crucible below the upper heater to apply heat to a lower portion of the crucible, with the lower heater operable independently of the upper heater so that the heat applied by the upper heater and the lower heater to the crucible can be selected, and heat insulation between the upper and lower heaters. The crucible is supported on an axially advanceable crucible support. In a crystal growth process in accordance with the invention, the crucible is initially filled with a feed charge of the crystal to be grown, for example, GaAs doped with InAs, and the upper and lower heaters are operated to melt the feed material, which is then thoroughly mixed. The feed is then solidified, for example, by turning off the heaters and withdrawing the crucible from the heater region to cause rapid cooling and freezing of the melt. The upper and lower heaters are then turned back on and the crucible advanced into the heater area, with the upper heater raising the temperature of an upper portion of the crucible above the melting point of the feed material while the lower heater maintains a lower portion of the crucible at a temperature which is below the melting point of the feed material. Where needed, a liquid encapsulant (e.g., B₂O₃ for use with GaAs) is deposited over the melt layer. To begin crystal growth, a seed crystal pulling rod is advanced through the encapsulant into the melt to initiate crystal growth from the melt onto the seed. The pulling rod with the seed and growing crystal on it is then drawn upwardly and rotated as the crystal grows to pull the growing crystal out of the melt layer and through the liquid encapsulant. As the crystal rod is drawn from the melt, the crucible is raised to bring some of the solid feed material into the heating zone of the upper heater, which raises the temperature of this solid material sufficiently to melt it and thus replenish the melt drawn out by the crystal.

Because only a single crucible is required in the present invention, there are no passageways or orifices to be clogged, and the large majority of the original solid feed material is used in the process so that the amount of waste feed material left at the end of the process is greatly reduced as compared to double crucible processes. The present invention is also well suited to the production of semiconductor alloys, such as alloys of InAs and GaAs. Because of the natural convection occurring in the melt as a result of the temperature gradients in the melt from the top to the bottom of the melt layer, the melt remains well mixed and stratification due to settling of heavier constituents in the melt is avoided.

Further objects, features, and advantages of the invention will be apparent from the following detailed description when taken in conjunction with the accompanying drawings.

### BRIEF DESCRIPTION OF THE DRAWINGS

In the drawings:

FIG. 1 is a simplified cross-sectional view of apparatus for carrying out homogeneous crystal growth in accordance with the invention.

FIG. 2 are graphs showing InAs axial concentration distributions in a GaAs crystal of 0.04 mol % InAs for a crystal grown by the conventional Czochralski process and for a crystal grown in accordance with the invention.

FIG. 3 is a graph of InAs radial concentration distribution in the crystal of FIG. 2 that was grown in accordance with the invention.

FIG. 4 are graphs showing InAs axial concentration distributions in a GaAs crystal of 0.1 mol % InAs for a crystal grown by the conventional Czochralski process and for a crystal grown in accordance with the present invention.

FIG. 5 is a graph illustrating InAs radial concentration distribution in the crystal of FIG. 4 that was grown in accordance with the invention.

FIG. 6 is a graph showing InAs axial concentration distribution in a GaAs-InAs alloy crystal grown in accordance with the invention.

FIG. 7 is a graph showing InAs radial concentration distribution in the alloy crystal of FIG. 6.

FIG. 8 is another graph of InAs axial concentration distribution in a GaAs-InAs alloy crystal grown in accordance with the present invention at a higher InAs concentration than for the crystal of FIGS. 6 and 7.

FIG. 9 is a graph showing InAs radial concentration distribution in the alloy crystal of FIG. 8.

### DETAILED DESCRIPTION OF THE INVENTION

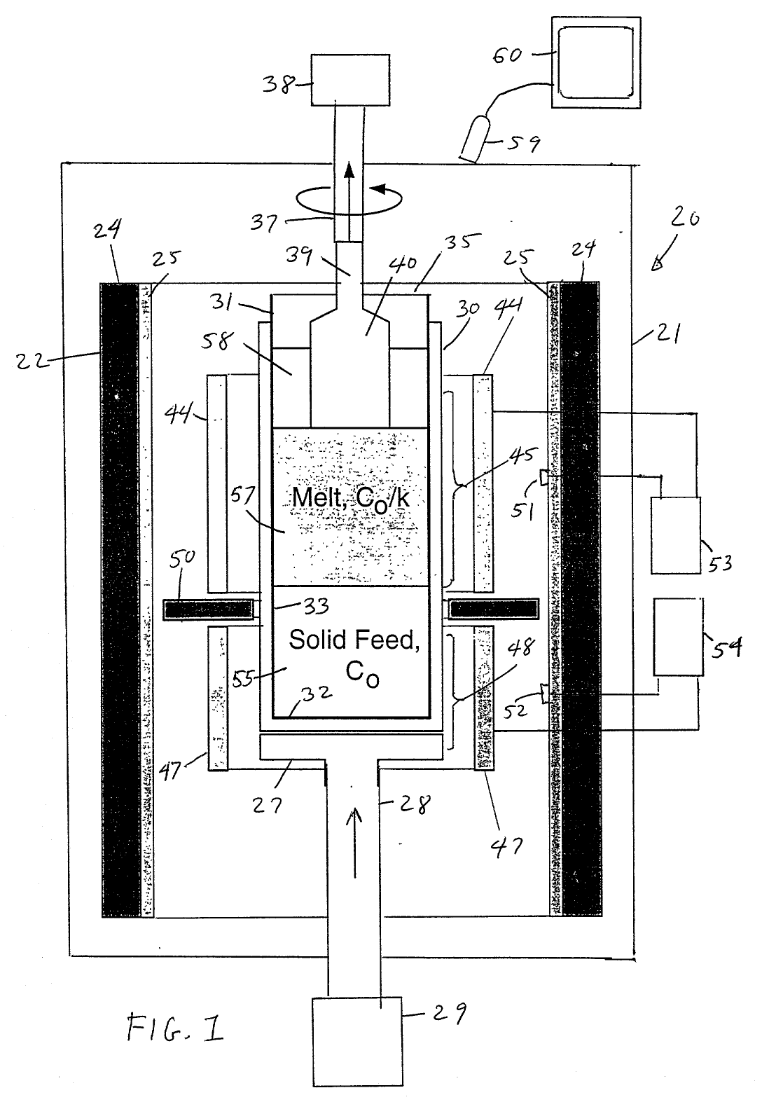

With reference to the drawings, apparatus for homogeneous crystal growth in accordance with the invention is shown generally at 20 in FIG. 1. The apparatus 20 includes an outer enclosure or chamber 21 of conventional design, within which are mounted an insulating enclosure 22, formed, e.g., of an outer layer of graphite felt insulation 24 and an inner graphite shield 25, of cylindrical configuration. A crucible support 27 (e.g., of graphite) is mounted at the end of a support rod 28 that extends outside of the enclosure 21 in a conventional fashion to a conventional driving mechanism 29 that selectively pushes the rod 28 and crucible support 27 upwardly at a controlled rate (and which may also rotate the support 27, if desired). A crucible holder 30 is mounted on the crucible support 27 and contains within it an axially extending crucible 31 which has a preferably flat bottom 32, a (typically cylindrical) sidewall 33 and an open top end 35. The crucible holder 30 and the crucible 31 may be unitary elements, and can be considered together as a crucible. A separate inner crucible 31 as shown in FIG. 1 is desirable for use with materials such as GaAs which may be reactive with or contaminated by conventional crucible materials. For example, the crucible 31 may be formed of a relatively thin walled pyrolytic BN (PBN) material which will be highly stable in contact with a GaAs melt, while the physical support provided by the holder 30 (e.g., of graphite) allows the thickness of the walls of the relatively expensive inner crucible 31 to be minimized. As shown schematically in FIG. 1, a crystal pulling rod 37 extends out of the enclosure 21 to a conventional drive 38 for pulling and rotating the rod 37. A seed crystal 39 is mounted at the end of the rod 37, and the growing crystal 40 forms attached to the seed 39 and is drawn upwardly as the rod 37, driven by the drive 38, raises and rotates the crystal.

In the present invention, an upper heater 44 is positioned around an upper portion 45 of the crucible 31 and crucible holder 30. A lower heater 47 is positioned to surround a lower portion 48 of the crucible 31 and crucible holder 30. The lower heater 47 is positioned below the upper heater 44, and a heat insulator 50 is positioned between the upper heater 44 and the lower heater 47. The heaters 44 and 47 may be of conventional design, e.g., electrically powered graphite heaters of cylindrical construction. The insulator 50 is preferably formed of a durable heat insulating material, such as graphite felt supported by graphite, that can withstand the high temperatures within the growth chamber. It also preferably has a cylindrical form, with an inner surface spaced closely adjacent to the outer surface of the crucible holder 30. The insulator 50 is positioned intermediate the top 35 and bottom 32 of the crucible 31 and effectively divides the upper section 45 of the crucible that is heated by the upper heater 44 from the lower section 48 of the crucible that is heated by the lower heater 47. The heaters 44 and 47 are provided with electrical power independently of one another so that the amount of heat that they apply to the portions of the crucible adjacent to them can be independently controlled, to thereby allow independent control of the temperature of the crucible and its contents in the upper region 45 and in the lower region 48. The insulator 50 helps to maintain the difference in temperature between the upper region 45 and the lower region 48. Temperature sensors 51 and 52, e.g., thermocouples, may be mounted in the insulating enclosure 22 adjacent to the upper heater 44 and lower heater 47, respectively, to allow the temperatures of the heaters 44 and 47 to be monitored and controlled by controllers 53 and 54, respectively. The controllers 53 and 54, of conventional design, are connected to supply power to the heaters 44 and 47 to maintain their temperatures at desired levels.

In the present invention, the crucible 31 is relatively long in the axial direction with respect to its diameter as compared with conventional crucibles. A relatively high aspect ratio of length to diameter (e.g., 1.5 to 5) is preferred to allow the crucible 31 to be filled with a solid feed charge 55 that is initially significantly greater in volume than the volume of melt material that will be required to allow growth of the crystal. In carrying out the present invention, the crucible 31 may initially be filled with a mix of the solid feed particles, e.g., particles of InAs mixed with particles of GaAs. This solid feed is then covered by a layer of the encapsulant (e.g., B₂O₃). This charge is then melted (e.g., by turning on both of the heaters 44 and 47 to apply high heat), thoroughly mixed, and then cooled to a solid (e.g., by turning off the heaters). The crucible support 27 is drawn downwardly to a lowermost position at which the layer of encapsulant and a top portion of the solid feed material are surrounded by the upper heater 44, while the rest of the solid feed 55 is positioned below the insulator 40 and is surrounded by the heater 47. The heaters 44 and 47 are then supplied with power to heat the crucible 31 and its contents, with the temperature of the upper region 45 being raised by the heater 44 above the melting point of the solid feed 55 and above the melting point of the encapsulant, resulting in a layer 57 of feed melt above the solid feed 55, and a layer of liquid encapsulant 58 over the melt layer 57, as shown in FIG. 1. The seed crystal 39 is then advanced downwardly by the rod 38 into contact with the melt 57 and, after crystallization begins, is slowly drawn upwardly and rotated by the rod 37 to draw the crystal 40 out of the melt 57 and through the encapsulant 58. Zone leveling of dopant in the melt may be utilized, as discussed further below. The drawing of the crystal 40 draws material away from the melt 57. This material is replaced by selective advancing of the crucible 31 upwardly by the crucible support 27 so that more of the solid feed 55 is advanced into the hotter zone 45 which is heated by the upper heater 44. The newly melted material which is added to the melt layer 57 has the uniform dopant concentration of the solid feed 55, thereby tending to maintain the desired dopant concentration in the melt layer 57 despite the effects of segregation of dopant that may occur as the crystal 40 is withdrawn from the melt 57. Typically, the upper heater is reduced a few degrees in temperature to allow seeding and at the same time the lower heater is increased a few degrees to prevent the melt depth from shrinking. After the melt temperature has stabilized, the seed is allowed to grow by further lowering the upper heater temperature by a few degrees and at the same time raising the lower heater temperature by a few degrees. The rate of advancement of the crucible support 27 to raise the crucible 31 may be controlled in coordination with the drawing of the crystal 40 out of the melt in a conventional fashion to maintain a melt layer 57 at a desired volume and dopant concentration. For example, a video camera 59 (e.g., a CCD camera) may be mounted at a viewing port in the enclosure 21 to display a picture of the melt surface and the growing crystal 40 on a monitor 60, allowing an operator to adjust the speed of the drives 29 and 38.

The following are examples of crystal growth as carried out in accordance with the present invention.

An apparatus for crystal growth was used as shown schematically in FIG. 1. The crucible 31 was 30 mm inside diameter (ID) by 33 mm outside diameter (OD) by 85 mm in height. In order to reduce cost, silica crucibles were used rather than pyrolytic BN. The upper graphite heater 44 applied heat to the melt 57 and the lower heater 47 applied heat to the solid feed 55. The depth of the melt 57 was determined by lowering a 1.5 mm diameter probe of quartz or alumina into the crucible 31 along the crucible wall. A pyrolytic BN-coated rod could be used as a probe if a pyrolytic BN crucible were used. For a typical experiment the depth of the melt 57 was from about 30 to 35 mm and its variation during crystal growth was about ±0.5 mm.

In order to grow a crystal at a targeted InAs concentration C₀, the compositions of the growth melt 57 and the solid feed 55 were set at C₀/k and C₀, respectively, according to the concept of zone leveling, where k is an experimentally determined constant. A k value of 0.116 was experimentally measured for In-doped GaAs in a previous study under similar crystal growth conditions.

The procedure for preparing the solid feed and the melt was as follows: a charge consisting of 6N GaAs, 6N InAs and 5N B₂O₃ (<200 ppm H₂O) was loaded in the crucible. The amounts of GaAs and InAs were such that the solid feed of the targeted composition C₀ could be prepared. To grow a crystal of the targeted composition C₀=0.04 mol % InAs, the charge consisted of 230 g GaAs, 0.1224 g InAs and 20 g B₂O₃. The B₂O₃depth was 16 mm, the melt depth was 32.5 mm and the initial length of the solid feed was 29 mm. The amount of InAs added to the melt 57 for zone leveling was 0.4887 g. This was expected to raise the melt composition to about 0.348 mol % (=0.04 mol %/0.115), based on a selected k value of 0.115.

To grow a crystal of the targeted composition of C₀=0.1 mol % InAs, the charge consisted of 233.5 g GaAs, 0.3088 g InAs and 20 g B₂O₃. The amount of InAs added to the melt for zone leveling was 1.2540 g. The melt was 33 mm deep and the solid feed was initially 29 mm long.

Both heaters 44 and 47 were turned on to melt the charge. After 4 h of mixing at about 1245° C., the melt was allowed to solidify rapidly to minimize macrosegregation in the resultant ingot. Since the melt is separated from the crucible wall by a thin layer of molten B₂O₃, large undercooling of the melt can be achieved easily. This was done suddenly by lowering the crucible 31 to below the heaters 44 and 47 and turning-off the heaters immediately. An undercooled melt tends to freeze instantaneously, leaving no time for solute segregation to develop over a long distance that is comparable to the crucible dimension. This rapid solidification is different from directional solidification, which does not reduce macrosegregation. The melt remained in the liquid state with a mirror-like free surface until it solidified instantaneously with a dull top surface, suggesting rapid solidification of an undercooled melt.

Immediately after freezing, the crucible was raised back into the heaters and the heaters were turned back on. The power of the lower heater 47, however, was set at a reduced level that was predetermined to give the desired melt depth. After 2 h InAs was added to the melt to level (adjust) the melt composition to C₀/k. The melt was then allowed to mix for 4 h. After seeding, the power of the upper heater 44 was reduced slightly to allow the seed to grow. The power of the lower heater 41 was raised slightly to help reduce the change in the melt depth.

Crystals were pulled in the [100] direction at 4 mm/h and rotated at 20 rpm. The crucible was raised at the speed V_{c}=Vₛ(dₛ/d_{c})² where Vₛ is the crystal pulling speed, dₛ the crystal diameter and d_{c} the inner diameter of the crucible. The Ar pressure in the chamber 21 was 6.76×10⁵ Pa (98 psi).

The InAs concentration was measured in the resultant crystals in the axial and radial directions by inductively coupled plasma mass spectrometry (ICPMS). Samples about 0.5 g each were removed from the crystals, dissolved in HC1:HNO₃ 3:1 and then diluted with distilled water to 100 cm³.

In the single-crucible LEC process of the present invention, the melt temperature can be adjusted, either for the seed to grow or for adjusting the crystal diameter, which can cause the melt depth to change. The heat applied by upper heater 44 and the lower heater 47 can be adjusted to help reduce such changes in the melt depth.

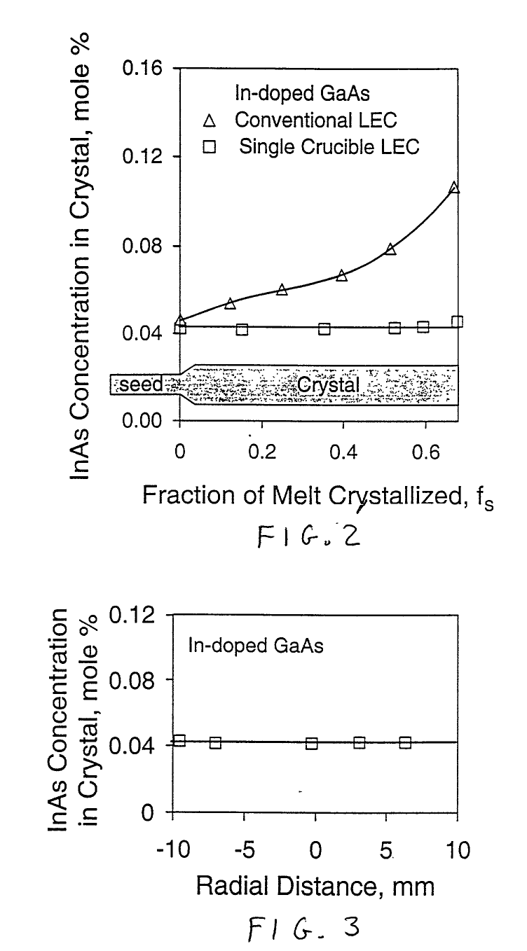

FIGS. 2 and 3 show the dopant segregation in a rod of GaAs crystal grown with the targeted composition of C₀=0.04 mol % InAs. The InAs concentration is essentially uniform in the axial direction in the crystal of the present invention, as shown in FIG. 2. The InAs concentration in the radial direction, measured in the crystal rod at about 33 mm from the seed end of the crystal, is also uniform, as shown in FIG. 3. This uniform composition of the crystal suggests that the segregation control technique is effective. The axial InAs concentration profile in a similar crystal grown by the conventional LEC process, also included in FIG. 2, shows the expected dopant segregation that occurs in the conventional LEC process.

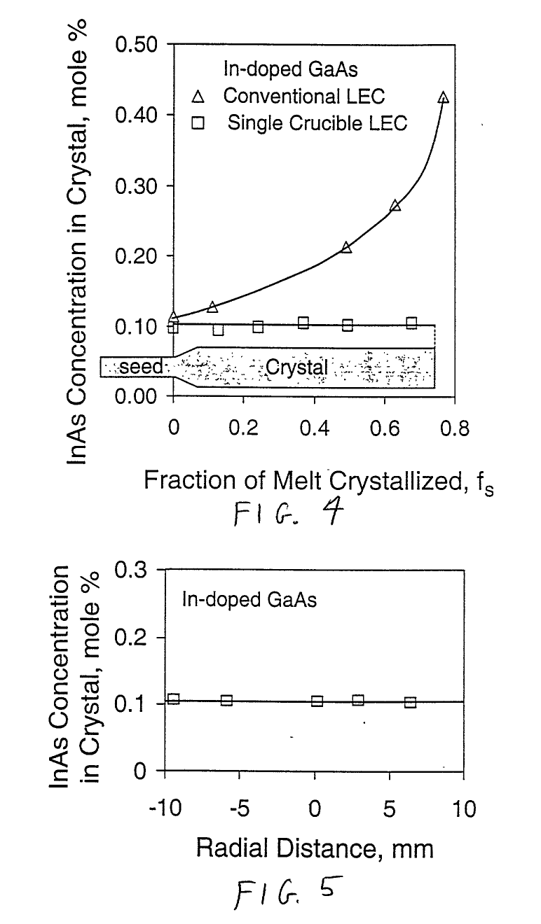

FIGS. 4 and 5 show the dopant segregation in a rod of GaAs crystal grown with the targeted composition of C₀=0.1 mol % InAs. Again, the InAs concentration in the crystal rod grown by the present invention is essentially uniform in the axial direction, as shown in FIG. 4. The InAs concentration in the radial direction, measured at 50 mm from the seed end of the crystal rod is also uniform, as shown in FIG. 5. The axial distribution of dopant in a crystal rod grown by the conventional LEC process is also shown in FIG. 4 for comparison.

The effectiveness of segregation control also depends on the compositional uniformity of the solid feed. The compositional uniformity of the solid feed was not checked in the example above. However, an ingot of Ga₁₋ₓInₓAs alloy was prepared using the procedure described above. The ingot was 3 cm in diameter and 3.5 cm high, and the composition was 28.5 ±1 mol % InAs throughout the ingot. This indicates that solid feed of uniform compositions can be prepared by such procedures.

Fused silica is relatively soft at the crystal growth temperature of GaAs, and if there is a tendency for a silica crucible to crack during the preparation of the solid feed, it cannot be detected if a fused silica crucible is used. An experiment was conducted to find out if the procedure for preparing the solid feed would also work with PBN crucibles. A PBN crucible, obtained from Union Carbide (of the same dimensions as the fused silica crucibles described above), was used, and no signs of cracking were observed.

The present invention may also be utilized to provide crystal growth of alloys to achieve solid crystals in which the alloy concentration is highly uniform both axially and radially. As noted, control over segregation is not feasible in the standard Czochralski process. Segregation control has been feasible in the double-crucible Czochralski process (with a bottom opening in the inner crucible and without an encapsulant) for doped crystals but not crystal alloys. Because the compositions of the growth melt and the replenishing melt are very different in alloy crystal growth (because of the wide gap in the phase diagram), the densities and the freezing temperatures can be significantly different. Consequently, two problems have been encountered in crystal growth with Czochralski processes. First, the two melts can mix suddenly due to the density difference. Second, the outer melt can freeze during crystal growth. The present invention can be utilized to avoid these problems.

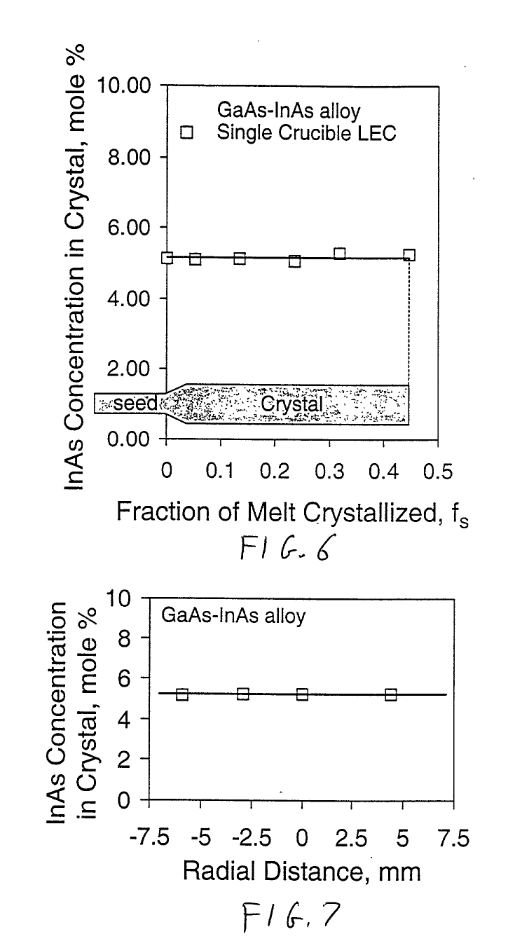

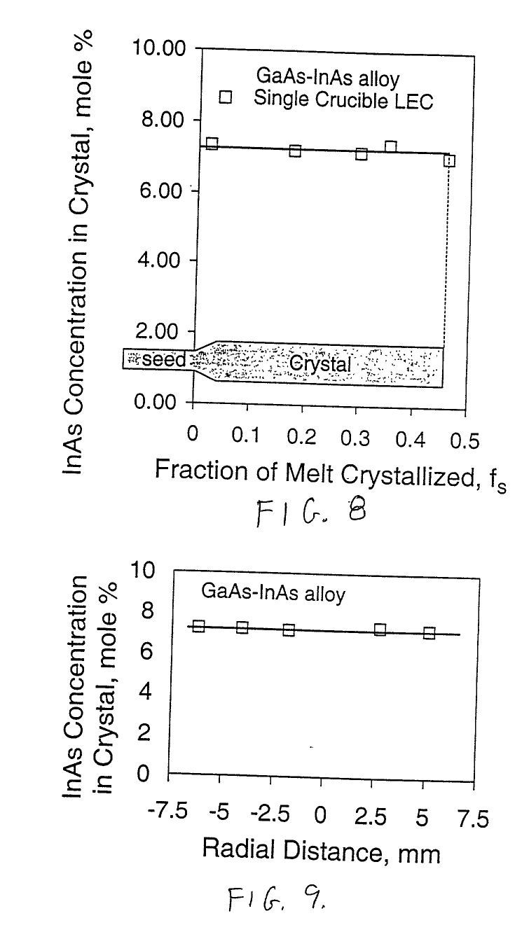

As an example of alloys produced in accordance with the invention, the foregoing processing was carried out utilizing much higher percentages of InAs in the initial feed than are used for In-doping. FIGS. 6 and 7 illustrate InAs axial concentration and radial concentration, respectively, for a crystal produced by the foregoing procedure with an InAs concentration of about 5 mol %. FIGS. 8 and 9 show InAs axial concentration and radial concentration, respectively, for a crystal produced by the foregoing procedure with an InAs concentration of over 7 mol %. These graphs show that the axial and radial concentrations of the alloy are extremely constant, with a variation from the initial InAs concentration over the length of the crystal rod of less than 5 percent of the initial concentration level. The present invention may also be used to grow alloy crystals of other materials, for example, GaP—InP and GaP—GaAs, and may also be used to grow alloys that do not need an encapsulant (e.g., SiGe, NaNO₃—KNO₃, etc.). Conventional double crucible systems with a bottom opening in the inner crucible are not as well suited to growing alloy crystals because the growth melt can be heavier than the replenishing melt and thus leak out through the bottom opening of the inner crucible. In the present invention, the heaters 44 and 47 maintain the uppermost portion of the melt 57 at a higher temperature than the lowermost portion of the melt, resulting in convection mixing in the melt due to temperature gradients, thereby maintaining the uniformity of the melt.

It is understood that the invention is not confined to the particular embodiments set forth herein, but embraces all such forms thereof as come within the scope of the following claims.

What is claimed is:

1. Apparatus for carrying out Czochralski crystal growth comprising:
(a) a crucible having a bottom, a sidewall and an open top, with an axial height from the open top to the bottom;
(b) an upper heater around the crucible to apply heat to an upper portion of the crucible;
(c) a lower heater around the crucible below the upper heater to apply heat to a lower portion of the crucible, the lower heater operable independently of the upper heater so that the heat applied by the upper heater and the lower heater to the crucible can be selected;
(d) heat insulation between the upper and lower heaters; and
(e) an axially advanceable crucible support under the crucible on which the crucible is supported.

2. The apparatus of claim 1 including means for drawing a solidified crystal from liquid melt in the crucible through the open top of the crucible.

3. The apparatus of claim 1 including heat insulation around and spaced outwardly from the upper and lower heaters.

4. The apparatus of claim 1 further including a solid feed material occupying a lower portion of the crucible, a liquid melt of the feed material over the solid material which occupies a region of the crucible above the solid feed material, a liquid encapsulant material over the liquid melt occupying a region of the crucible above the liquid melt, and means for drawing a solidified crystal from the liquid melt through the liquid encapsulant.

5. The apparatus of claim 4 wherein the top of the solid feed material in the crucible is at a height adjacent to the insulation between the upper and lower heaters.

6. The apparatus of claim 4 wherein the means for drawing the crystal also rotates the crystal being drawn from the melt.

7. The apparatus of claim 4 wherein the solid feed material is In-doped GaAs and the liquid melt is In-doped GaAs.

8. The apparatus of claim 4 wherein the solid feed material is an alloy of GaAs and InAs.

9. The apparatus of claim 1 further including a temperature sensor positioned to sense the temperature of the lower heater in the region of the solid feed material and a temperature sensor positioned to sense the temperature of the heater in the region of the liquid feed melt material.

10. The apparatus of claim 1 wherein the aspect ratio of the axial length of the crucible to the diameter of the crucible is at least 2 to 1.

11. The apparatus of claim 1 wherein the crucible comprises an outer crucible holder and an inner crucible held within the crucible holder.

12. The apparatus of claim 11 wherein the inner crucible is formed of pyrolytic BN.

13. A method of carrying out Czochralski crystal growth comprising:
(a) providing a crucible with a solid feed material therein having a desired concentration of constituents for the crystal to be grown;
(b) heating an upper portion of the crucible with an upper heater to a temperature sufficient to melt the feed material in an upper portion of the crucible and separately heating a lower portion of the crucible with a lower heater to another temperature which is below the melt temperature of the feed material so that the feed material in the lower portion of the crucible remains solid;
(c) growing a crystal from the melt and drawing the growing crystal out of the melt;
(d) advancing the crucible with respect to the heaters as the crystal is drawn from the melt to heat additional portions of solid feed material with the upper heater to melt the additional solid material to replace the crystal drawn from the melt.

14. The method of claim 13 further including rotating the crystal as it is drawn from the melt.

15. The method of claim 13 further including covering the melt with a liquid encapsulant material while growing the crystal from the melt and drawing the growing crystal out of the melt.

16. The method of claim 15 wherein the feed material is In-doped GaAs.

17. The method of claim 16 wherein the liquid encapsulant material is B₂O₃.

18. The method of claim 15 wherein the feed material is an alloy of InAs and GaAs.

19. The method of claim 18 wherein the liquid encapsulant is B₂O₃.

20. The method of claim 13 wherein the feed material is SiGe.

21. The method of claim 13 wherein the step of providing a crucible with a solid feed material therein includes filling the crucible with a mixture of particulate feed material having the desired concentration of constituents, heating the particulate material to melt it in the crucible and thoroughly mixing the melted material, then freezing the melted material to form a solid feed material in the crucible, and then heating an upper portion of the feed material in the crucible with the upper heater to a temperature above the melting temperature of the material.

22. The method of claim 13 wherein the step of growing a crystal from the melt includes contacting the melt with a seed crystal at an end of a crystal pulling rod to grow crystal from the melt onto the seed and then drawing the rod upwardly to draw the growing crystal from the melt.

23. The method of claim 22 further including reducing the heat applied by the upper heater after the seed crystal contacts the melt to lower the temperature of the melt to allow crystal to grow on the seed.

24. The method of claim 23 further including raising the heat applied by the lower heater to the solid feed material after the seed crystal contacts the melt to raise the temperature of the solid feed material and melt an additional portion of the solid feed material to reduce the change in the depth of the melt as the crystal is grown on the seed.

25. The method of claim 13 wherein the crucible is advanced with respect to the heaters at a speed V_{c}=Vₛ (dₛ/d_{c})², where Vₛ is the speed at which the crystal is drawn from the melt, dₛ is the diameter of the crystal as drawn from the melt, and d_{c} is the inner diameter of the crucible.

26. The method of claim 13 wherein before drawing the crystal from the melt, the melt is leveled by the addition of a desired dopant to adjust the melt concentration to a level Cₒ/k, where Cₒ is the desired dopant concentration in the crystal and k is an experimentally determined constant.

27. The method of claim 13 further including maintaining the crucible in an enclosure containing an inert gas atmosphere.

28. The method of claim 13 wherein the upper and lower heaters maintain the uppermost portion of the melt at a higher temperature than the lowermost portion of the melt to maintain a temperature gradient in the melt to enhance convection mixing of the melt.

29. A method of carrying out liquid encapsulated Czochralski crystal growth comprising:
(a) providing a crucible with a solid feed material therein having a desired concentration of constituents for the crystal to be grown;
(b) heating an upper portion of the crucible with an upper heater to a temperature sufficient to melt the feed material in an upper portion of the crucible and separately heating a lower portion of the crucible with a lower heater to another temperature which is below the melt temperature of the feed material so that the feed material in the lower portion of the crucible remains solid;
(c) growing a crystal from the melt and drawing the growing crystal out of the melt while covering the melt with a liquid encapsulant material;
(d) advancing the crucible with respect to the heaters as the crystal is drawn from the melt to heat additional portions of solid feed material with the upper heater to melt the additional solid material to replace the crystal drawn from the melt.

30. The method of claim 29 further including rotating the crystal as it is drawn from the melt.

31. The method of claim 29 wherein the feed material is In-doped GaAs.

32. The method of claim 31 wherein the liquid encapsulant material is B₂O₃.

33. The method of claim 29 wherein the feed material is an alloy of InAs and GaAs.

34. The method of claim 33 wherein the liquid encapsulant is B₂O₃.

35. The method of claim 29 wherein the step of growing a crystal from the melt includes contacting the melt with a seed crystal at an end of a crystal pulling rod to grow crystal from the melt onto the seed and then drawing the rod upwardly to draw the growing crystal from the melt and through the liquid encapsulant.

36. The method of claim 29 wherein before drawing the crystal from the melt, the melt is leveled by the addition of a desired dopant to adjust the melt concentration to a level Cₒ/k, where Cₒ is the desired dopant concentration in the crystal and k is an experimentally determined constant.

37. The method of claim 29 wherein the step of providing a crucible with a solid feed material therein includes filling the crucible with a mixture of particulate feed material having the desired concentration of constituents and the encapsulant, heating the particulate material to melt it in the crucible and thoroughly mixing the melted material, then freezing the melted material to form a solid feed material in the crucible, and then heating an upper portion of the feed material in the crucible with the upper heater to a temperature above the melting temperature of the material.
